(19) United States
(12) Patent Application Publication
(10) Pub. No.: US 2024/0347550 A1
(43) Pub. Date: Oct. 17, 2024

(54) DRIVING BACKPLANE AND PREPARATION METHOD THEREFOR, AND DISPLAY APPARATUS

(71) Applicant: BOE Technology Group Co., Ltd., Beijing (CN)

(72) Inventors: Yang LV, Beijing (CN); Feng GUAN, Beijing (CN); Jianhua DU, Beijing (CN); Meng ZHAO, Beijing (CN); Hao WU, Beijing (CN); Chaolu WANG, Beijing (CN)

(73) Assignee: BOE Technology Group Co., Ltd., Beijing (CN)

(21) Appl. No.: 18/755,700

(22) Filed: Jun. 27, 2024

Related U.S. Application Data
(63) Continuation of application No. PCT/CN2021/142178, filed on Dec. 28, 2021.

(51) Int. Cl. H01L 27/12

(52) U.S. Cl. CPC H01L 27/1251; H01L 27/1222; H01L 27/124; H01L 27/127

(57) ABSTRACT

A method for preparing a driving backplane includes: providing a base substrate, forming a connecting layer on a side of the base substrate; forming an insulating layer group on a side of the connecting layer away from the base substrate, forming a first via hole by patterning the insulating layer group; forming inducing particles on a side of the insulating layer group away from the base substrate; forming a doped amorphous silicon layer on a side of the inducing particles away from the base substrate, forming a first conductor part by the doped amorphous silicon layer formed in the first via hole, forming a raw material part by patterning the doped amorphous silicon layer; and forming a first channel part by causing the inducing particles to induce the raw material part, wherein the first channel part is connected to the first conductor part.

### CROSS-REFERENCE TO RELATED APPLICATION

This application is a continuation of PCT application No. PCT/CN2021/142178, filed Dec. 28, 2021, entitled “DRIVING BACKPLANE AND PREPARATION METHOD THEREFOR, AND DISPLAY APPARATUS,” which is hereby incorporated by reference in its entirety.

### TECHNICAL FIELD

This disclosure relates to the field of display technology and, in particular, to a driving backplane, a method for preparing the driving backplane, and a display device including the driving backplane.

### BACKGROUND

LTPS (Low Temperature Poly-silicon) display panel has the advantages of ultra-thin, light weight, low power consumption, and ability to provide more vivid colors and clearer images, thereby attracting widespread attention.

However, the current thin film transistors of LTPS are prone to occur defects of failure to be conductive.

It should be noted that the information disclosed in the above background section is only used to enhance understanding the background of this disclosure, and therefore may include information that does not constitute prior art known to those skilled in the art.

### SUMMARY

This disclosure is directed to overcome the shortcomings of related art mentioned above, thereby providing a driving backplane, a method for preparing the driving backplane, and a display device including the driving backplane.

According to an aspect of this disclosure, a method for preparing a driving backplane is provided and includes:
providing a base substrate, and forming a connecting layer on a side of the base substrate;
forming an insulating layer group on a side of the connecting layer away from the base substrate, and forming a first via hole by patterning the insulating layer group, wherein the first via hole is connected to the connecting layer;
forming inducing particles on a side of the insulating layer group away from the base substrate;
forming a doped amorphous silicon layer on a side of the inducing particles away from the base substrate and the side of the insulating layer group away from the base substrate, forming a first conductor part by the doped amorphous silicon layer formed in the first via hole, and forming a raw material part by patterning the doped amorphous silicon layer, wherein the first conductor part is connected to the connecting layer, and the raw material part is connected to the first conductor part; and
forming a first channel part by causing the inducing particles to induce the raw material part, wherein the first channel part is connected to the first conductor part.

In an exemplary embodiment of this disclosure, a guide groove is formed on a surface of the insulating layer group away from the base substrate upon forming the first via hole by patterning the insulating layer group, where the guide groove extends along a first direction, and the first via hole is connected to the guide groove.

In an exemplary embodiment of this disclosure, a second conductor part is formed upon forming the raw material part by patterning the doped amorphous silicon layer, where the second conductor part is connected to the raw material part and is formed on a side of the raw material part away from the first conductor part.

In an exemplary embodiment of this disclosure, the raw material part is formed within the guide groove, and the second conductor part is formed on a side of the guide groove away from the first conductor part.

In an exemplary embodiment of this disclosure, the inducing particles are formed within the guide groove, and a diameter of the inducing particles is greater than or equal to 100 nanometers and less than or equal to 300 nanometers.

In an exemplary embodiment of this disclosure, a width of the guide groove in a second direction is greater than or equal to 1 micron and less than or equal to 5 microns, and a depth of the guide groove in a third direction is greater than or equal to 100 nanometers and less than or equal to 120 nanometers, where the second direction is perpendicular to the first direction, and the third direction is perpendicular to both the first direction and the second direction.

In an exemplary embodiment of this disclosure, the first channel part is formed by growing along a groove sidewall of the guide groove extending along the first direction.

In an exemplary embodiment of this disclosure, before forming the inducing particles, the method further includes:
forming an inducing layer on the side of the insulating layer group away from the base substrate;
where the inducing particles are formed by performing pattern processing and reduction processing on the inducing layer, a material of the inducing layer is indium tin oxide or indium, and the inducing particles are indium metal particles.

In an exemplary embodiment of this disclosure, a material of the doped amorphous silicon layer is N-type doped amorphous silicon, and the first channel part is a polysilicon nanowire.

In an exemplary embodiment of this disclosure, the first channel part further includes residue of the inducing particles and N-type doping.

In an exemplary embodiment of this disclosure, the connecting layer is a second active layer, the second active layer includes a second channel part and a third conductor part provided at both ends of the second channel part, and the first conductor part is connected to the third conductor part.

According to another aspect of this disclosure, a driving backplane is provided and includes:
a base substrate;
a connecting layer, provided on a side of the base substrate;
an insulating layer group, provided on a side of the connecting layer away from the base substrate, where the insulating layer group is provided with a first via hole, and the first via hole is connected to the connecting layer;
a first conductor part, provided within the first via hole, where the first conductor part is connected to the connecting layer;
a first channel part, provided on a side of the insulating layer group away from the base substrate and connected to the first conductor part, where an orthographic projection of the first channel part on the base substrate overlaps with an orthographic projection of the connecting layer on the base substrate.

In an exemplary embodiment of this disclosure, a guide groove is provided on a surface of the insulating layer group away from the base substrate, the guide groove extends along a first direction, and the first channel part is located on a groove sidewall of the guide groove extending along the first direction.

In an exemplary embodiment of this disclosure, the driving backplane further includes:
a second conductor part, provided on the side of the insulating layer group away from the base substrate, where the second conductor part is connected to the first channel part, and is located on a side of the guide groove away from the first conductor part.

In an exemplary embodiment of this disclosure, the driving backplane further includes:
inducing particles, provided between the second conductor part and the first channel part.

In an exemplary embodiment of this disclosure, the first channel part is a polysilicon nanowire, and the first channel part further includes residue of the inducing particles and N-type doping.

In an exemplary embodiment of this disclosure, the connecting layer is a second active layer, the second active layer includes a second channel part and a third conductor part provided at both ends of the second channel part, and the first conductor part is connected to the third conductor part.

In an exemplary embodiment of this disclosure, the insulating layer group includes a first gate insulating layer, a second gate insulating layer and a second buffer layer stacked in sequence, the first gate insulating layer is provided on a side of the connecting layer away from the base substrate, a second via hole is provided to penetrate through the first gate insulating layer and the second gate insulating layer, and the driving backplane further includes:
a second gate, provided between the first gate insulating layer and the second gate insulating layer, and opposite to the first channel part;
a second source, provided between the second gate insulating layer and the second buffer layer, and connected to the third conductor part through the second via hole;
a third gate insulating layer provided on a side of the first channel part away from the base substrate;
a first gate, provided on a side of the third gate insulating layer away from the base substrate, and opposite to the first channel part;
a fourth gate insulating layer, provided on a side of the first gate away from the base substrate, where a third via hole is provided to penetrate through the third gate insulating layer and the fourth gate insulating layer; and
a first source, provided on a side of the fourth gate insulating layer away from the base substrate, and is connected to the second conductor part through the third via hole.

In an exemplary embodiment of this disclosure, the driving backplane further includes:
a third thin film transistor, provided on a side of the base substrate, where a third active layer of the third thin film transistor is provided in a same layer and a same material as the second active layer;
a fourth thin film transistor, provided on the side of the base substrate, where a fourth active layer of the fourth thin film transistor is provided in the same layer and the same material as the second active layer;
a fifth thin film transistor, provided on a side of the third thin film transistor away from the base substrate; and
a sixth thin film transistor, provided on a side of the fourth thin film transistor away from the base substrate.

In an exemplary embodiment of this disclosure, a fifth active layer of the fifth thin film transistor and a sixth active layer of the sixth thin film transistor are provided in a same layer and a same material of metal oxide.

According to yet another aspect of this disclosure, a display device is provided and includes any one of the driving backplanes described above.

It should be understood that the foregoing general description and the following detailed description are exemplary and explanatory only without limiting this disclosure.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure. Obviously, the drawings in the following description are only some embodiments of this disclosure. For those skilled in the art, other drawings can be obtained based on these drawings without exerting creative efforts.

FIG. 1 is a schematic flow chart of a method for preparing a driving backplane according to an exemplary embodiment of this disclosure.

FIG. 2 is a schematic structural diagram of forming a connecting layer on a base substrate.

FIG. 3 is a schematic structural diagram after forming a second gate on the basis of FIG. 2.

FIG. 4 is a schematic structural diagram after forming a second via hole on the basis of FIG. 3.

FIG. 5 is a schematic structural diagram after forming a second source on the basis of FIG. 4.

FIG. 6 is a schematic structural diagram after forming a first via hole on the basis of FIG. 5.

FIG. 7 is a schematic top view of the structure of FIG. 6.

FIG. 8 is a schematic top view after forming the first via hole, according to another exemplary embodiment, on the basis of FIG. 5.

FIG. 9 is a schematic structural diagram after forming an inducing part on the basis of FIG. 6.

FIG. 10 is a schematic top view of the structure of FIG. 9.

FIG. 11 is a schematic structural diagram after forming an inducing part on the basis of FIG. 8.

FIG. 12 is a schematic diagram of a partial structure of inducing particles formed on the basis of FIG. 9.

FIG. 13 is a schematic structural diagram after forming a first conductor part, a second conductor part and a raw material part on the basis of FIG. 9.

FIG. 14 is a schematic top view of the structure of FIG. 13.

FIG. 15 is a schematic structural diagram after forming a first conductor part, the second conductor part and the raw material part on the basis of FIG. 11.

FIG. 16-FIG. 18 are schematic diagrams showing the principle of growing silicon nanowire.

FIG. 19 is a schematic structural diagram after forming a first channel part on the basis of FIG. 13.

FIG. 20 is a schematic top view of the structure of FIG. 19.

FIG. 21 is a schematic structural diagram after forming a first channel part on the basis of FIG. 15.

FIG. 22 is a schematic structural diagram after forming a first gate on the basis of FIG. 19.

FIG. 23 is a schematic structural diagram of a driving backplane according to an exemplary embodiment of this disclosure.

FIG. 24 is a schematic characteristics diagram of the first thin film transistor in FIG. 23.

FIG. 25 is a schematic structural diagram of a driving backplane according to another exemplary embodiment of this disclosure.

FIG. 26 is a schematic circuit diagram of FIG. 25.

### EXPLANATION OF REFERENCE SIGNS

1. base substrate;
2. second active layer; 2a. connecting layer; 21. second channel part; 22. third conductor part; 23. third channel part; 24. fourth channel part; 25. fourth conductor part;
3. insulating layer group; 31. first gate insulating layer; 32. second gate insulating layer; 33. second buffer layer; 34. first via hole; 35. guide groove;
4. inducing part; 41. inducing particle; 42. metal alloy droplet; 43. crystal nucleus;
51. first conductor part; 52. second conductor part; 53. raw material part; 54. first channel part;
61. first gate; 62. second gate; 63. third gate; 64. fourth gate; 65. fifth gate; 66. sixth gate;
71. first source; 72. second source; 73. fifth source; 74. connecting part;
81. third gate insulating layer; 82. fourth gate insulating layer; 83. third buffer layer; 84. fifth gate insulating layer; 85. sixth gate insulating layer; 86. interlayer dielectric layer; 87. planarization layer;
91. fifth active layer; 911. fifth channel part; 912. fifth conductor part; 92. sixth active layer; 921. sixth channel part; 922. sixth conductor part;
101. second via hole; 102. third via hole; 103. fourth via hole; 104. fifth via hole; 105. sixth via hole; 106. seventh via hole;
11. electrode layer;
X. first direction; Y. second direction; Z. third direction; C. capacitor;
T1. first thin film transistor; T2. second thin film transistor; T3. third thin film transistor; T4. fourth thin film transistor; T5. fifth thin film transistor; T6. sixth thin film transistor.

### DETAILED DESCRIPTION

Example embodiments will now be described more fully with reference to the accompanying drawings. Example embodiments may, however, be embodied in many forms and should not be construed as limited to the embodiments set forth herein; rather, these embodiments are provided so that this disclosure will be thorough and complete, and will fully convey the concept of example embodiments to those skilled in the art. The same reference numerals in the drawings denote the same or similar structures, and thus their detailed descriptions will be omitted. Furthermore, the drawings are merely schematic illustrations of this disclosure and are not necessarily drawn to scale.

Although relative terms such as “upper” and “lower” are used in this specification to describe the relative relationship of one component of an icon to another component, these terms are used in this specification only for convenience, for example, according to the description in the accompanying drawings directions for the example described above. It will be appreciated that if the illustrated device is turned over so that it is upside down, then elements described as being “upper” will become elements that are “lower”. When a structure is “on” another structure, it may mean that a structure is integrally formed on another structure, or that a structure is “directly” placed on another structure, or that a structure is “indirectly” placed on another structure through another structure. other structures.

The terms “a”, “an”, “the”, “said” and “at least one” are used to indicate the presence of one or more elements/components/etc; the terms “comprising” and “have” are used to indicate an open and means that there may be additional elements/components/etc. in addition to the listed elements/components/etc.; the terms “first”, “second” and “third” etc. only Used as a marker, not a limit on the number of its objects.

The inventor found that: when the active layer of the thin film transistor is connected to other conductive layers through the via hole, the semiconductor material formed in the via hole cannot be subjected to the excimer laser annealing process and the doping process, so that the semiconductor material in the via hole cannot form a conductor, so that the active layer cannot be connected to other layers through the via hole, and then there is a problem of inability to conduct.

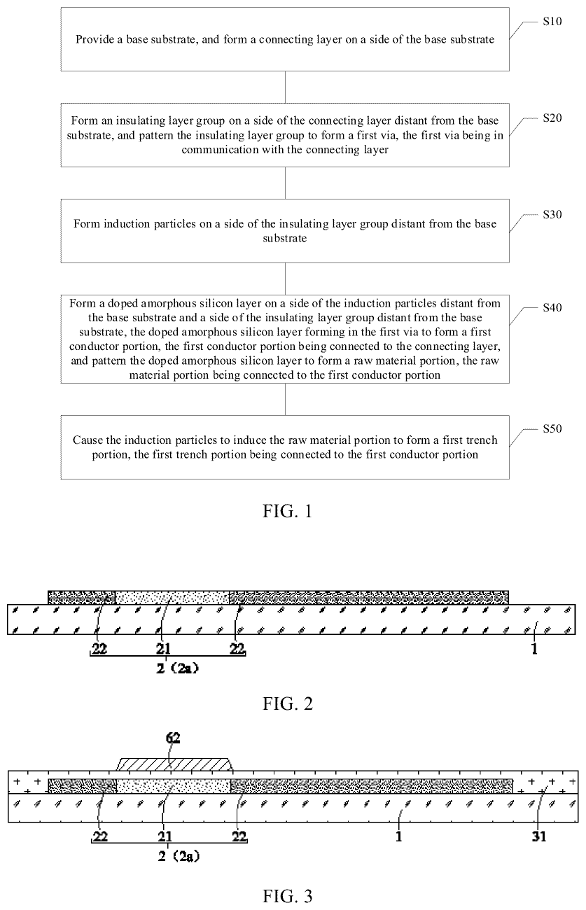

An exemplary embodiment of this disclosure provides a method for preparing a driving backplane. Referring to FIG. 1, the method for preparing the driving backplane may include the following steps:

In step S10, a base substrate 1 is provided, and a connecting layer is formed on one side of the base substrate 1.

Step S20, forming an insulating layer group 3 on the side of the connecting layer away from the base substrate 1, and patterning the insulating layer group 3 to form a first via hole 34, the first via hole 34 connected to the connecting layer.

Step S30, forming inducing particles 41 on the side of the insulating layer group 3 away from the base substrate 1.

Step S40, forming a doped amorphous silicon layer on the side of the inducing particles 41 away from the base substrate 1 and the side of the insulating layer group 3 away from the base substrate 1, and the doped amorphous silicon layer The crystalline silicon layer is formed in the first via hole 34 to form a first conductor part 51, the first conductor part 51 is connected to the connecting layer, and the doped amorphous silicon layer is patterned to form a raw material part 53, the raw material part 53 is connected to the first conductor part 51.

In step S50, the inducing particles 41 induce the raw material part 53 to form a first channel part 54, and the first channel part 54 is connected to the first conductor part 51.

In the driving backplane and the manufacturing method of the driving backplane disclosed in this disclosure, the doped amorphous silicon layer is formed in the first via hole 34 to form the first conductor part 51, the first conductor part 51 is connected to the connecting layer 2a, and the doped amorphous silicon layer The silicon layer also forms a raw material part 53, the raw material part 53 is connected to the first conductor part 51, and the inducing particle 41 induces the raw material part 53 to form a first channel part 54, and the first channel part 54 is connected to the first conductor part 51; The amorphous silicon layer is a conductor, and excimer laser annealing process and doping process are not required, and the first channel part 54 and the connecting layer 2a can be well connected through the first conductor part 51, so that the active layer can pass through The via hole is connected to other layers, and there will be no defects that cannot be conducted.

Each step of the method for preparing the driving backplane will be described in detail below.

In step S10, a base substrate 1 is provided, and a connecting layer 2 a is formed on one side of the base substrate 1.

In this exemplary embodiment, the material of the base substrate 1 may include an inorganic material, for example, the inorganic material may be glass, quartz, or metal. The material of the base substrate 1 may also include organic materials, for example, the organic materials may be polyimide, polycarbonate, polyacrylate, polyetherimide, polyethersulfone, polyethylene terephthalate Resin materials such as ester and polyethylene naphthalate. The base substrate 1 may be formed of multiple material layers, for example, the base substrate 1 may include multiple base layers, and the material of the base layer may be any one of the above-mentioned materials. Of course, the base substrate 1 can also be set as a single layer, which can be any one of the above materials.

A light-shielding layer (not shown) can also be formed on one side of the base substrate 1, and the light injected into the active layer from the base substrate 1 will generate photocarriers in the active layer, thereby affecting the characteristics of the thin film transistor. It has a huge impact, and finally affects the display quality of the display device; the light incident from the base substrate 1 can be blocked by the light-shielding layer, so as to avoid affecting the characteristics of the thin film transistor and the display quality of the display device.

A first buffer layer (not shown) can also be formed on the side of the light-shielding layer away from the base substrate 1, and the first buffer layer plays a role in blocking water vapor and impurity ions in the base substrate 1 (especially organic materials). function, and play the role of adding hydrogen ions to the subsequently formed active layer, the material of the first buffer layer is an insulating material, which can insulate and isolate the light shielding layer from the active layer.

In this exemplary embodiment, as shown in FIG. 2, the second active layer 2 is formed on the side of the first buffer layer away from the base substrate 1, and a part of the second active layer 2 is formed by a conductorization process. The third conductor part 22 enables the second active layer 2 to include a second channel part 21 and two third conductor parts 22 provided at two ends of the second channel part 21 in one-to-one correspondence.

It should be noted that, after the gate 62 is formed, the third conductor part 22 can be formed by performing a conductorization process on a part of the second active layer 2 by using the gate 62 as a mask. The conductorization process can be ion implantation.

Step S20, forming an insulating layer group 3 on the side of the connecting layer 2a away from the base substrate 1, and patterning the insulating layer group 3 to form a first via hole 34, the first via hole 34 communicates with the connecting layer 2a.

In this example embodiment, as shown in FIG. A second gate material layer is formed on the side, and then the second gate material layer is patterned to form a second gate 62.

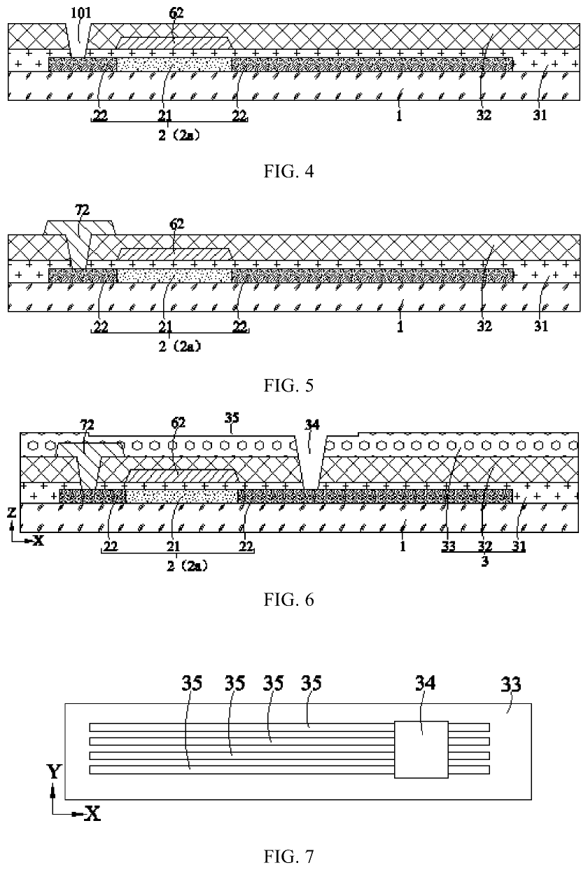

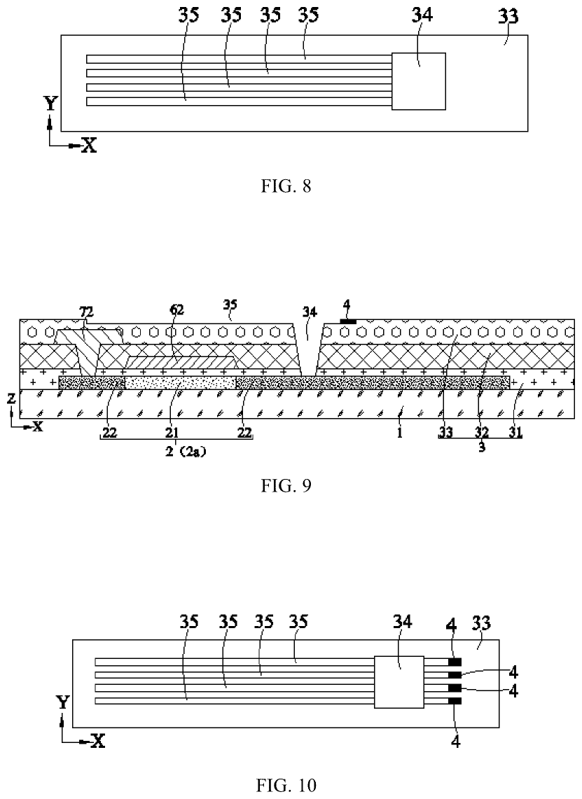

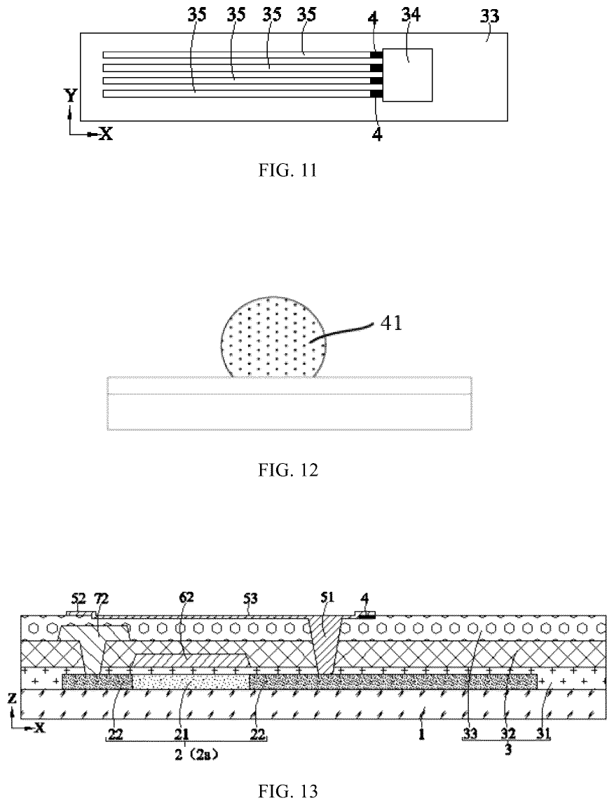

Referring to FIG. 4, the second gate insulating layer 32 is formed on the side of the second gate 62 away from the base substrate 1; referring to FIG. 5, the second gate insulating layer 32 is formed on the side away from the base substrate 1. The second source-drain material layer, and then patterning the second source-drain material layer to form the second source electrode 72.

The second channel part 21, the third conductor part 22, the second gate 62, and the second source 72 or the second drain form a low temperature polysilicon type second thin film transistor T2, and the low temperature polysilicon type second thin film transistor T2 is the top gate type. Of course, in other exemplary embodiments of this disclosure, the second thin film transistor T2 may be of a bottom-gate type or a double-gate type, and its specific structure will not be repeated here.

Referring to FIG. 6, the second buffer layer 33 is formed on the side of the second source electrode 72 away from the base substrate 1. The second buffer layer 33, the second gate insulating layer 32 and the first gate insulating layer 31 form the insulating layer group 3.

The insulating layer group 3 is patterned to form a first via hole 34 and a guide groove 35, and the first via hole 34 is connected to the third conductor part 22 of the second active layer 2. Referring to FIG. 7, one first via hole 34 is connected to a plurality of guide grooves 35. The first via hole 34 may be located at one end of the plurality of guide grooves 35, and both ends of the plurality of guide grooves 35 protrude from the first via hole 34. A plurality of guide grooves 35 extend along the first direction X, and a plurality of guide grooves 35 are provided at intervals in the second direction Y, that is, there is a gap between two adjacent guide grooves 35, and the width of the gap is greater than or equal to 1 μm and less than or equal to 5 μm. The first direction X intersects the second direction Y, for example, the first direction X and the second direction Y may be perpendicular. The guide groove 35 may include a groove bottom wall and two groove sidewalls extending along the first direction X, and the groove sidewalls are the sidewalls in the height direction of the guide groove 35, that is, the sidewalls substantially perpendicular to the base substrate 1, the bottom wall of the groove is the side wall of the guide groove 35 close to the base substrate 1, that is, the bottom wall substantially parallel to the base substrate 1. In addition, in other exemplary embodiments of this disclosure, as shown in FIG. A via 34.

It should be noted that it is difficult to achieve less than 1 μm with the current equipment process capability. Therefore, the width of the gap is greater than or equal to 1 μm; there is no upper limit for the width of the gap, but if the width is too large, the size of the first thin film transistor T1 will be too large. The design requirements can be judged by oneself, therefore, the above data are only for illustration and do not constitute a limitation to this disclosure; after the process is improved, the width of the gap can also be other values.

The width of the guide groove 35 in the second direction Y is greater than or equal to 1 micron and less than or equal to 5 microns. The depth of the guide groove 35 in the third direction Z is greater than or equal to 100 nanometers and less than or equal to 120 nanometers, the third direction Z is the depth direction of the guide groove 35, and the third direction Z is perpendicular to the first direction X and the second direction Y. The length of the guide groove 35 in the first direction X may be equal to or greater than the length of the first channel part 54 to be formed.

It should be noted that it is very difficult to achieve below 1 μm with the current equipment process capability. Therefore, the width of the guide groove 35 is greater than or equal to 1 μm; there is no upper limit for the width of the guide groove 35, but if the width is too large, the first thin film transistor T1 will be damaged. If the size is too large, it needs to be judged according to the design requirements. Therefore, the above data is only for illustration and does not constitute a limitation of this disclosure; after the process is improved, the width of the guide groove 35 can also be other values.

The guide groove 35 can provide a guide for the first channel part 54 formed subsequently, so that the length of the first channel part 54 can be grown longer to meet product requirements.

Step S30, forming inducing particles 41 on the side of the insulating layer group 3 away from the base substrate 1.

In this exemplary embodiment, an inducing layer is formed on a side of the second buffer layer 33 away from the base substrate 1, and the material of the inducing layer may be indium tin oxide (ITO). 9 and 10, the inducing layer is patterned to form the induction portion 4, the induction portion 4 is formed at one end of the guide groove 35 close to the first via hole 34, that is, the first via hole 34 and the induction portion 4 are formed at the same end of the guide groove 35. The thickness of the inducing layer is greater than or equal to 150 nm and less than or equal to 500 nm. Certainly, in other exemplary embodiments of this disclosure, the material of the inducing layer may also be indium metal, indium zinc oxide (IZO) and the like. Referring to 11, the inducing portion 4 is formed at one end of the guide groove 35 connected to the first via hole 34.

Then, reduction treatment is performed on the inducing part 4 to form the inducing particles 41, specifically, as shown in reference to 12, the inducing part 4 is subjected to reduction treatment by H plasma to form the inducing particles 41. The inductive particles 41 may be indium metal particles. Utilizing the low eutectic point of In (indium) and Si (silicon), Si can be continuously precipitated from the saturated eutectic and crystallized to form planar silicon nanowires, which is easy to implement in terms of technology and low in cost. The diameter of the inducing particle 41 is greater than or equal to 100 nanometers and less than or equal to 300 nanometers. Of course, in other exemplary embodiments of this disclosure, the inducing particles 41 may also be other metal particles, such as Ni, Co, Al, etc.

Step S40, forming a doped amorphous silicon layer on the side of the inducing particles 41 away from the base substrate 1 and the side of the insulating layer group 3 away from the base substrate 1, and the doped amorphous silicon layer The crystalline silicon layer is formed in the first via hole 34 to form a first conductor part 51, the first conductor part 51 is connected to the connecting layer 2a, and the doped amorphous silicon layer is patterned to form a raw material part 53, the raw material part 53 is connected to the first conductor part 51.

In this exemplary embodiment, as shown in reference 13, a doped amorphous silicon layer is formed on the side of the inducing particles 41 away from the base substrate 1 and the side of the second buffer layer 33 away from the base substrate 1, and the doped amorphous silicon layer The silicon layer may be N-type doped amorphous silicon. N-type doped amorphous silicon is a conductor, and the N-type doped amorphous silicon formed in the first via hole 34 forms a first conductor part 51, and the first conductor part 51 is connected to the third conductor part 22, and the first conductor part 51 can be well connected to the third conductor part 22. Using indium metal particles as the inductive particles 41, In (indium) residues are inevitable, In (indium) can be used as doping of P-type doped amorphous silicon, and In (indium) residues will cause excessive leakage current of thin film transistors, cannot be turned off; while the N-type doping in the N-type doped amorphous silicon can neutralize the In (indium) residue, so the influence of the In (indium) residue on the formed first channel part 54 can be avoided. However, if the amorphous silicon layer is used as the raw material layer, In (indium) residues will be generated, resulting in excessive leakage current of the film transistor, which cannot be turned off. Of course, in other example embodiments of this disclosure, the doped amorphous silicon layer may also be P-type doped amorphous silicon.

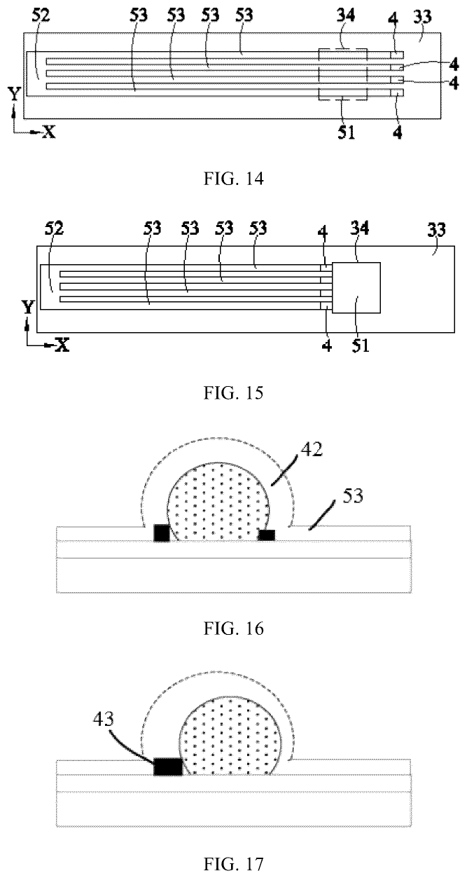

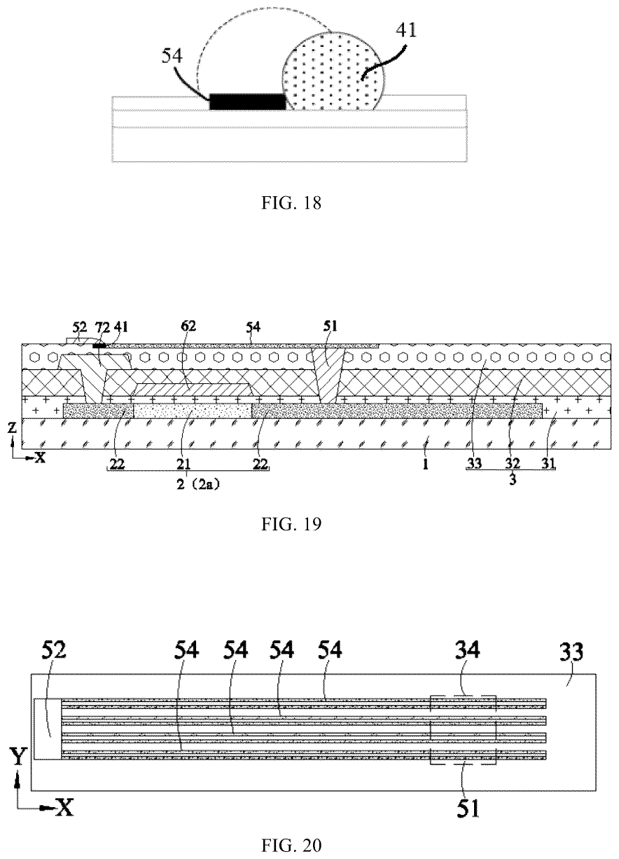

Please continue to refer to 13 and shown in FIG. 14, and then, the doped amorphous silicon layer is patterned to retain the doped amorphous silicon layer in the guide groove 35 to form the raw material part 53, and also retain the guide groove 35. The doped amorphous silicon layer on the side away from the first via hole 34 forms the second conductor part 52, that is, the second conductor part 52 is formed outside the guide groove 35 and is located on the side of the guide groove 35 away from the first via hole. 34 on one side. The raw material part 53 is connected to both the first conductor part 51 and the second conductor part 52. Of course, as shown in 15, when the first via hole 34 is connected to one end of the plurality of guide grooves 35, the first conductor part 51 and the second conductor are located on opposite sides of the raw material part 53.

In step S50, the inducing particles 41 induce the raw material part 53 to form a first channel part 54, and the first channel part 54 is connected to the first conductor part 51.

In this exemplary embodiment, the raw material part 53 located in the guide groove 35 can be induced by the In inducing particles 41 to form the first channel part 54. Specifically, as shown in 16, the raw material part 53 is annealed to form a metal For the alloy droplet 42, the annealing temperature is about 390 degrees; as shown in 17, when the concentration of Si in the metal alloy droplet 42 is oversaturated, crystal nuclei 43 are precipitated; as shown in 18, driven by the Gibbs free energy, the metal alloy The droplet of liquid 42 pulls the crystal nucleus 43 to grow into a silicon nanowire, that is, generates a first channel part 54, the first channel part 54 is a polycrystalline silicon nanowire, and the first channel part also includes N-type doping and inducing particles 41 residues (eg, indium residues).

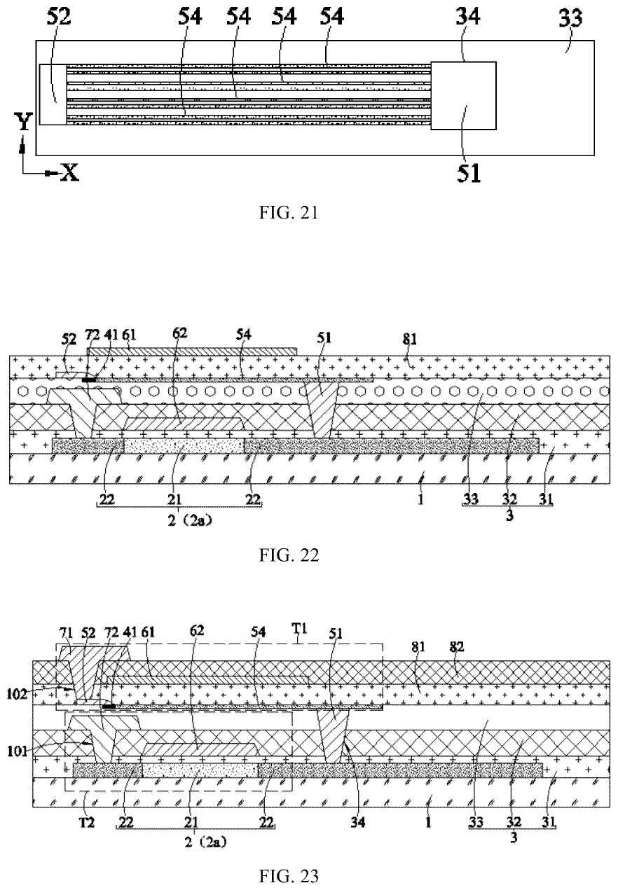

It should be noted that, as shown in FIG. The side wall of the groove extending along the first direction X, therefore, two first channel parts 54 are formed in one guide groove 35, the width of the first channel part 54 is greater than or equal to 30 nm and less than or equal to 100 nm, the first groove The length of the channel part 54 is substantially equal to the length of the guide groove 35; the height of the first channel part 54 is also substantially equal to the depth of the guide groove 35, that is, the height of the first channel part 54 is greater than or equal to 100 nanometers and less than or equal to 120 nanometers. Since the guide groove 35 protrudes from the first via hole 34, both ends of the formed first channel part 54 protrude from the first conductor part 51. Of course, as shown in FIG. 21, in the case where the first conductor part 51 and the second conductor are located on opposite sides of the raw material part 53, the first conductor part 51 and the second conductor are located on opposite sides of the first channel part 54.

After the inducing particle 41 induces the raw material part 53 to form the first channel part 54, the inducing particle 41 can be etched away, and the inducing particle 41 can also be retained; because the inducing particle 41 induces the first channel part 54 from the first conductor part 51 One side grows toward the second conductor part 52 side, therefore, the remaining inducing particles 41 are located between the second conductor part 52 and the first channel part 54. Of course, when the inducing particles 41 induce the first channel part 54 to grow from the second conductor part 52 side to the first conductor part 51 side, the remaining inducing particles 41 are located between the first conductor part 51 and the first channel part. Between section 54.

It should be noted that it is difficult to achieve the current process capability below 30 nm, therefore, the width of the first channel part 54 is greater than or equal to 30 nm; when the width of the first channel part 54 is greater than 100 nm, the drain of the first thin film transistor T1 The current will be very large, affecting the performance of the first thin film transistor T1. Therefore, the width of the first channel part 54 is less than or equal to 100 nm; after the process is improved, the width of the first channel part 54 can also be other values.

In addition, the first conductor part 51 can not only be provided in the first via hole 34, but can also extend to the side of the second buffer layer 33 away from the substrate, so that the length of the guide groove can be set shorter, of course The length of the formed first channel part is also short.

So far, the preparation of the first active layer is completed.

Referring to FIG. 22, a third gate insulating layer 81 is formed on the side of the first active layer away from the base substrate 1, and a first gate material layer is formed on the side of the third gate insulating layer 81 away from the base substrate 1, The first gate material layer is patterned to form a first gate 61, and the first gate 61 is provided opposite to the first channel part 54.

Referring to FIG. 23, a fourth gate insulating layer 82 is formed on the side of the first gate 61 away from the base substrate 1; and the fourth gate insulating layer 82 and the third gate insulating layer 81 are patterned to form a third The via hole 102 and the third via hole 102 pass through the fourth gate insulating layer 82 and the third gate insulating layer 81 to connect to the second conductor part 52.

A first source-drain material layer is formed on the side of the fourth gate insulating layer 82 away from the base substrate 1, and the first source-drain material layer is patterned to form the first source 71, and the first source 71 passes through the third The via hole 102 is connected to the second conductor part 52.

The first channel part 54, the second conductor part 52, the first gate 61 and the first source 71 form a low temperature polysilicon type first thin film transistor T1, and the low temperature polysilicon type thin film transistor is a top gate type. Of course, in other exemplary embodiments of this disclosure, the second thin film transistor T2 may be of a bottom-gate type or a double-gate type, and its specific structure will not be repeated here.

It should be noted that although the steps of the manufacturing method of the driving backplane in this disclosure are described in a specific order in the drawings, this does not require or imply that these steps must be performed in this specific order, or that all steps must be performed. The steps shown are required to achieve the desired result. Additionally or alternatively, certain steps may be omitted, multiple steps may be combined into one step for execution, and/or one step may be decomposed into multiple steps for execution, etc.

Based on the same inventive concept, exemplary embodiments of this disclosure provide a driving backplane, which can be prepared by any one of the methods for preparing the driving backplane described above.

Referring to FIG. 23, the driving backplane may include a base substrate 1, a light-shielding layer (not shown in the figure) is provided on one side of the base substrate 1, and a light-shielding layer is provided on a side away from the base substrate 1. The first buffer layer (not shown in the figure).

A second active layer 2 is provided on the side of the first buffer layer away from the base substrate 1, and the second active layer 2 may include a second channel part 21, and be provided on the second channel part 21 in a one-to-one correspondence. Two third conductor parts 22 at both ends. A first gate insulating layer 31 is provided on the side of the second active layer 2 away from the base substrate 1, and a second gate 62 is provided on the side of the first gate insulating layer 31 away from the base substrate 1. The second gate The pole 62 is provided opposite to the second channel part 21. A second gate insulating layer 32 is provided on the side of the second gate 62 away from the base substrate 1, and a second via hole 101 penetrating through the first gate insulating layer 31 and the second gate insulating layer 32 is also provided. The hole 101 communicates to the third conductor part 22. A second source 72 is provided on a side of the second gate insulating layer 32 away from the base substrate 1, and the second source 72 is connected to the third conductor part 22 through the second via hole 101. Of course, the second source 72 can also be the second drain.

The second channel part 21, the third conductor part 22, the second gate 62 and the second source 72 form a low temperature polysilicon type second thin film transistor T2, and the low temperature polysilicon type second thin film transistor T2 is a top gate type. Of course, in other exemplary embodiments of this disclosure, the second thin film transistor T2 may be of a bottom-gate type or a double-gate type, and its specific structure will not be repeated here.

A second buffer layer 33 is provided on a side of the second source electrode 72 away from the base substrate 1. The second buffer layer 33, the second gate insulating layer 32, and the first gate insulating layer 31 form an insulating layer group 3.

A first via hole 34 is provided on the insulating layer group 3, that is, the first via hole 34 penetrates through the second buffer layer 33, the second gate insulating layer 32, and the first gate insulating layer 31. The first via hole 34 is connected to the third conductor part 22 on the side of the second channel part 21 away from the second source 72. A first conductor part 51 is provided in the first via hole 34, and the first conductor part 51 is connected to the third conductor part 22 on the side of the second channel part 21 away from the second source 72. The three conductor parts 22 are conductively connected.

20 and 21, a plurality of guide grooves 35 are provided on the side of the insulating layer group 3 away from the base substrate 1, that is, a plurality of guide grooves are provided on the side of the second buffer layer 33 away from the base substrate 1. Slot 35. One ends of the plurality of guide grooves 35 are connected to the first via holes 34. In this exemplary embodiment, the guide groove 35 may be provided in a straight line, and a plurality of guide grooves 35 are provided at intervals and in parallel.

Of course, in other example embodiments of this disclosure, the guide groove 35 may be set in a curved shape. It should be noted that the curve may be formed by connecting multiple arc lines, or may be formed by connecting arc lines and straight lines, or may be formed by connecting multiple straight lines.

A first channel part 54 is provided in the guide groove 35, and one end of the first channel part 54 is connected to the first conductor part 51. Specifically, the first channel part 54 is located on the groove sidewall of the guide groove 35, therefore, the length of the first channel part 54 is substantially the same as that of the guide groove 35, and the width of the first channel part 54 is the same as that of the guide groove. The grooves 35 have substantially the same depth. Its specific structure has been described in detail above, so it will not be repeated here.

The orthographic projection of the first channel part 54 on the base substrate 1 overlaps with the orthographic projection of the connecting layer 2 a on the base substrate 1. That is, the orthographic projection of the first channel part 54 on the base substrate 1 overlaps with the orthographic projection of the second active layer 2 on the base substrate 1. Both the first channel part 54 and the second active layer 2 are opaque, so that the two are at least partially overlapped, the area of the opaque region can be reduced, and the area of the transparent region can be increased, thereby improving the driving backplane. The opening area increases the resolution of the entire display device.

In this exemplary embodiment, the driving backplane may further include a second conductor part 52, and the second conductor part 52 is provided on the side of the insulating layer group 3 away from the base substrate 1, specifically, the second conductor part 52 is provided on the second The second buffer layer 33 is away from the side of the substrate 1; the second conductor part 52 is connected to the first channel part 54, and is located on the side of the first channel part 54 away from the first conductor part 51, that is, the second conductor part 52 is connected to an end of the first channel part 54 away from the first conductor part 51. The second conductor part 52 may be provided at an end of the guide groove 35 away from the first conductor part 51, and the second conductor part 52 is not located in the guide groove 35.

The orthographic projection of the second conductor part 52 on the base substrate 1 also overlaps with the orthographic projection of the second active layer 2 on the base substrate 1.

In some exemplary embodiments of this disclosure, the driving backplane may further include inducing particles 41; since the inducing particles 41 induce the first channel part 54 to grow from the first conductor part 51 side to the second conductor part 52 side, Therefore, the remaining inducing particles 41 are located between the second conductor part 52 and the first channel part 54. Of course, when the inducing particles 41 induce the first channel part 54 to grow from the second conductor part 52 side to the first conductor part 51 side, the remaining inducing particles 41 are located between the first conductor part 51 and the first channel part. Between section 54. Of course, the inducing particles 41 may also be etched away, so that the first channel part 54 is directly connected to both the first conductor part 51 and the second conductor part 52.

Using indium metal particles as the inducing particles 41, In (indium) residues are unavoidable, the first channel part 54 is a polysilicon nanowire, and the first channel part 54 also includes N-type doping and the residue of the inducing particles 41 (for example, indium residue).

In this exemplary embodiment, a third gate insulating layer 81 is provided on the side of the first conductor part 51, the second conductor part 52, and the first channel part 54 away from the base substrate 1, and the third gate insulating layer 81 is provided with a first gate 61 on a side away from the base substrate 1, and the first gate 61 is provided opposite to the first channel part 54. A fourth gate insulating layer 82 is provided on a side of the first gate 61 away from the base substrate 1. A third via hole 102 is provided on the third gate insulating layer 81 and the fourth gate insulating layer 82, and the third via hole 102 penetrates through the third gate insulating layer 81 and the fourth gate insulating layer 82 to communicate with the second conductor part 52. A first source 71 is provided on the side of the fourth gate insulating layer 82 away from the base substrate 1, and the first source 71 is connected to the second conductor part 52 through the third via hole 102. Of course, the first source 71 may also be the first drain.

The first channel part 54, the first conductor part 51, the second conductor part 52, the first gate 61, and the first source 71 or the first drain form a low temperature polysilicon type first thin film transistor T1, the low temperature polysilicon The type of the first thin film transistor T1 is a top gate type. Of course, in other exemplary embodiments of this disclosure, the first thin film transistor T1 may be of a bottom-gate type or a double-gate type, and its specific structure will not be repeated here.

The orthographic projection of the second conductor part 52 on the base substrate 1 also overlaps with the orthographic projection of the second active layer 2 on the base substrate 1. The orthographic projection of the first gate 61 on the base substrate 1 also overlaps with the orthographic projection of the second active layer 2 on the base substrate 1. The orthographic projection of the first source electrode 71 on the base substrate 1 also overlaps with the orthographic projection of the second active layer 2 on the base substrate 1. That is, the first thin film transistor T1 and the second thin film transistor T2 are stacked, saving the planar layout of one thin film transistor; both the first thin film transistor T1 and the second thin film transistor T2 are opaque, so that the two thin film transistors are at least partially Overlapping can reduce the area of the opaque region, thereby increasing the area of the light-transmitting region, thereby increasing the opening area of the driving backplane, and improving the aperture ratio and resolution of the entire display device.

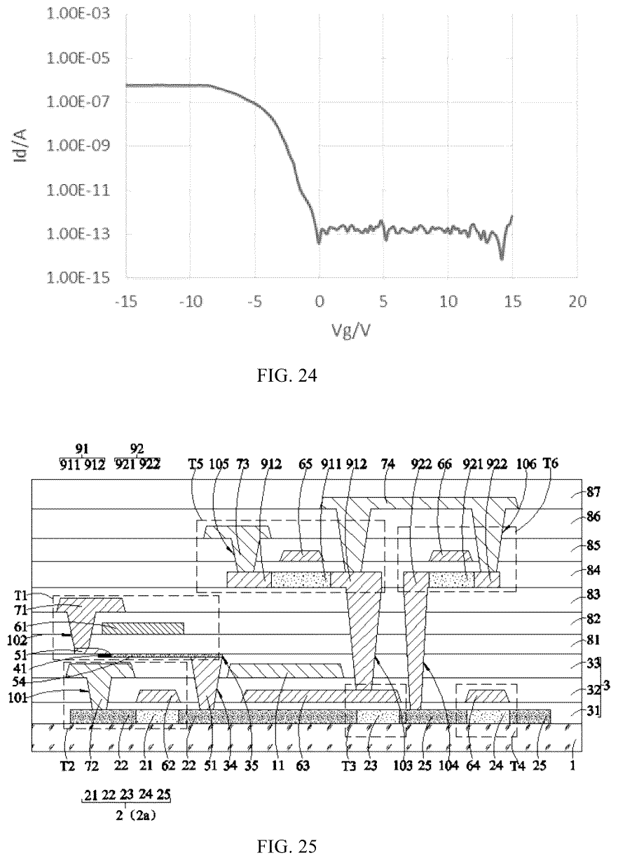

Referring to FIG. 24, in the figure Id is the drain current, the unit is A (amperes), Vg is the gate voltage, the unit is V (volts); when the first thin film transistor T1 works in the variable resistance region, Id approximately varies with Vg changes linearly. The first thin film transistor T1 works in a constant current region, and Id remains stable and does not change with changes in Vg. It has good characteristics and meets the use requirements of the driving backplane.

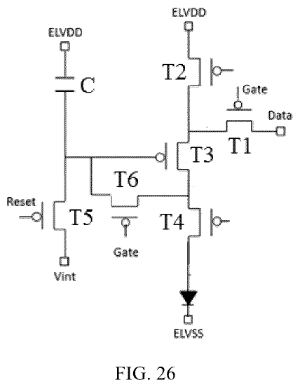

Referring to FIG. 25 and FIG. 26, each thin film transistor is marked by a dotted line in the figure. Since there is a connection between each thin film transistor, the position marked by the dotted line is only for the convenience of observation and subsequent description, and does not constitute a limitation to this disclosure. Gate is the gate line, ELVDD is the power line, Data is the data line, Reset is the reset line, ELVSS is the ground line, and Vint is the negative voltage line.

In another exemplary embodiment of this disclosure, the driving backplane may include six thin film transistors and a capacitor C, which are respectively the first thin film transistor T1, the second thin film transistor T2, the third thin film transistor T3, and the fourth thin film transistor T4. 1. The specific structures of the fifth thin film transistor T5 and the sixth thin film transistor T6; the first thin film transistor T1 and the second thin film transistor T2 have been described in detail above, and thus will not be repeated here.

The third thin film transistor T3 is provided on one side of the base substrate, and the third active layer (the third conductor part 22 and the third channel part 23) of the third thin film transistor T3 is the same layer and the same material as the second active layer 2. Setting; the fourth thin film transistor T4 is provided on one side of the base substrate, and the fourth active layer (the fourth conductor part 25 and the fourth channel part 24) of the fourth thin film transistor T4 is on the same layer as the second active layer 2 The same material is provided; the fifth thin film transistor T5 is provided on the side of the third thin film transistor T3 away from the base substrate; the sixth thin film transistor T6 is provided on the side of the fourth thin film transistor T4 away from the base substrate. Setting multiple thin film transistors in a stacked structure saves the planar layout of multiple thin film transistors, can reduce the area of the opaque area, thereby increasing the area of the light transmitting area, thereby increasing the opening area of the driving backplane, and improving the overall display device. Aperture ratio, resolution.

Referring to FIG. 25, the second active layer 2 has a larger area and can also serve as the active layer of the third thin film transistor T3 and the fourth thin film transistor T4. Specifically, the second active layer 2 may include a second channel part 21, a third channel part 23, and a fourth channel part 24 sequentially connected by conductor parts, corresponding to the two sides of the second channel part 21. Two third conductor parts 22 are provided, and two fourth conductor parts 25 are correspondingly provided on both sides of the fourth channel part 24. That is, the second active layer 2 may include a third conductor part 22, a second channel part 21, a third conductor part 22, a third channel part 23, a fourth conductor part 25, and a fourth channel part 24 connected in sequence. and the fourth conductor part 25.

The first gate insulating layer 31 completely covers the second active layer 2. A third gate 63 and a fourth gate 64 are also provided on the side of the first gate insulating layer 31 away from the base substrate 1, the third gate 63 and the fourth gate 64 are provided at intervals, and the third gate 63 and the fourth gate 64 are provided at intervals. The fourth gate 64 and the second gate 62 are formed through the same patterning process. The third gate 63 is provided opposite to the third channel part 23, and the fourth gate 64 is provided opposite to the fourth channel part 24. The area of the third gate 63 is set larger, and the third gate 63 can be used as an electrode of the capacitor C.

The second gate insulating layer 32 completely covers the second gate 62, the third gate 63, the fourth gate 64 and the exposed first gate insulating layer 31. The electrode layer 11 of the capacitor C is also provided on the side of the second gate insulating layer 32 away from the base substrate 1, and the electrode layer 11 of the capacitor C is formed through the same patterning process as the second source 72. The orthographic projection of the electrode layer 11 of the capacitor C on the base substrate 1 partially overlaps the orthographic projection of the third gate 63 on the base substrate 1, and the overlapped electrode layer 11 and the third gate 63 form a capacitor C.

A second buffer layer 33, a third gate insulating layer 81, a fourth gate insulating layer 82 and a third buffer layer 83 are sequentially stacked on the side of the electrode layer 11 away from the base substrate 1. The second buffer layer 33, the third gate insulating layer 81, the fourth gate insulating layer 82 and the third buffer layer 83 are all insulating layers. A fourth via hole 103 penetrating through the second gate insulating layer 32, the second buffer layer 33, the third gate insulating layer 81, the fourth gate insulating layer 82 and the third buffer layer 83 is also provided, and the fourth via hole 103 is connected to The third gate 63; is also provided with the first gate insulating layer 31, the second gate insulating layer 32, the second buffer layer 33, the third gate insulating layer 81, the fourth gate insulating layer 82 and the third buffer layer 83 The fifth via hole 104 communicates with the fourth conductor part 25 between the third channel part 23 and the fourth channel part 24.

A fifth active layer 91 and a sixth active layer 92 are provided on the side of the third buffer layer 83 away from the base substrate 1; the fifth active layer 91 and the sixth active layer 92 are provided at intervals, and the fifth active layer Both the layer 91 and the sixth active layer 92 are made of IGZO (Indium Gallium Zinc Oxide, Indium Gallium Zinc Oxide), and the fifth active layer 91 and the sixth active layer 92 are formed by the same patterning process. The fifth active layer 91 includes a fifth channel part 911 and two fifth conductor parts 912 provided on both sides of the fifth channel part 911. The sixth active layer 92 includes a sixth channel part 921 and two fifth conductor parts 912 provided on both sides of the fifth channel part 911. Two sixth conductor parts 922 on both sides of the six channel part 921. The fifth conductor part 912 is connected to the third gate 63 through the fourth via hole 103, and the sixth conductor part 922 is connected to the fourth channel part between the third channel part 23 and the fourth channel part 24 through the fifth via hole 104. conductor part 25.

A fifth gate insulating layer 84 is provided on a side of the fifth active layer 91, the sixth active layer 92 and the exposed third buffer layer 83 away from the substrate 1. A fifth gate 65 and a sixth gate 66 are provided on the side of the fifth gate insulating layer 84 away from the base substrate 1, the fifth gate 65 and the sixth gate 66 are provided at intervals, and are formed by the same patterning process. The fifth gate 65 is provided opposite to the fifth channel part 911, and the sixth gate 66 is provided opposite to the sixth channel part 921.

A sixth gate insulating layer 85 is provided on a side of the fifth gate 65, the sixth gate 66 and the exposed fifth gate insulating layer 84 away from the substrate 1. A sixth via hole 105 penetrating through the fifth gate insulating layer 84 and the sixth gate insulating layer 85 is also provided. conductor part 912.

A fifth source 73 is provided on the side of the sixth gate insulating layer 85 away from the base substrate 1, and the fifth source 73 is connected to the side of the fifth channel part 911 away from the sixth channel part 921 through the sixth via hole 105. The fifth conductor part 912 on one side.

An interlayer dielectric layer 86 is provided on a side of the fifth source electrode 73 and the exposed sixth gate insulating layer 85 away from the substrate 1. There are also two seventh via holes 106 penetrating through the interlayer dielectric layer 86, the fifth gate insulating layer 84 and the sixth gate insulating layer 85, and one of the seventh via holes 106 is connected to the fifth channel part 911 close to the first The fifth conductor part 912 on one side of the six channel part 921 communicates with the sixth conductor part 922 on the side of the sixth channel part 921 away from the fifth channel part 911 through another seventh via hole 106.

A connection portion 74 is provided on the side of the interlayer dielectric layer 86 away from the base substrate 1, and one end of the connection portion 74 is connected to the fifth channel part 911 close to the sixth channel part 921 through one of the seventh via holes 106. The fifth conductor part 912 on one side is connected to the sixth conductor part 922 on the side away from the fifth channel part 911 of the sixth channel part 921 through another seventh via hole 106. The fifth thin film transistor T5 and the sixth thin film transistor T6 are connected through the connection part 74.

A planarization layer 87 is provided on the side of the connection portion 74 and the exposed interlayer dielectric layer 86 away from the base substrate 1, and via holes can be provided on the planarization layer 87 to connect the driving backplane to other external structures.

It should be noted that the driving backplane may also include a capacitor C, three thin film transistors, seven thin film transistors, etc. The number of thin film transistors may also be other numbers, and its specific structure will not be described here.

Based on the same inventive concept, exemplary embodiments of this disclosure provide a display device, which may include any one of the driving backplanes described above. The specific structure of the driving backplane has been described in detail above, so it will not be repeated here.

The display device may be a quantum dot light emitting display device, an organic light emitting display device or a liquid crystal display device.

The quantum dot light-emitting display device may also include a quantum dot light-emitting device, and the quantum dot light-emitting device may include a first electrode, a quantum dot light-emitting layer, and a second electrode that are stacked.

The organic light-emitting display device can also be an organic light-emitting device, and the organic light-emitting device can include a first electrode, an organic electroluminescent layer, and a second electrode that are stacked.

The liquid crystal display device may also include a liquid crystal layer and a color filter substrate sequentially stacked on the side of the driving backplane, and may also include a backlight provided on the side of the driving backplane away from the liquid crystal layer.

The specific type of the display device is not particularly limited, and any type of display device commonly used in this field can be used, such as a mobile device such as a mobile phone, a wearable device such as a watch, a VR device, etc. The specific use of the corresponding selection, will not repeat them here.

It should be noted that, in addition to driving the backplane, the display device also includes other necessary components and components. Taking the display as an example, such as a casing, a circuit board, a power cord, etc., those skilled in the art can The specific usage requirements are supplemented accordingly, and will not be repeated here.

Compared with the prior art, the beneficial effects of the display device provided by the exemplary embodiments of this disclosure are the same as those of the driving backplane provided by the above exemplary embodiments, and will not be repeated here.

Other embodiments of the disclosure will be readily apparent to those skilled in the art from consideration of the specification and practice of the invention disclosed herein. This application is intended to cover any variations, uses, or adaptations of the disclosure that follow the general principles of the disclosure and include common knowledge or customary technical means in the technical field that are not disclosed in the disclosure. It is intended that the specification and examples be considered as exemplary only, with a true scope and spirit of the disclosure being indicated by the following claims.

What is claimed is:

1. A method for preparing a driving backplane, including:
providing a base substrate, and forming a connecting layer on a side of the base substrate;
forming an insulating layer group on a side of the connecting layer away from the base substrate, and forming a first via hole by patterning the insulating layer group, wherein the first via hole is connected to the connecting layer;
forming inducing particles on a side of the insulating layer group away from the base substrate;
forming a doped amorphous silicon layer on a side of the inducing particles away from the base substrate and the side of the insulating layer group away from the base substrate, forming a first conductor part by the doped amorphous silicon layer formed in the first via hole, and forming a raw material part by patterning the doped amorphous silicon layer, wherein the first conductor part is connected to the connecting layer, and the raw material part is connected to the first conductor part; and
forming a first channel part by causing the inducing particles to induce the raw material part, wherein the first channel part is connected to the first conductor part.

2. The method for preparing the driving backplane according to claim 1, further comprising, upon forming the first via hole by patterning the insulating layer group, forming a guide groove on a surface of the insulating layer group away from the base substrate, wherein the guide groove extends along a first direction, and the first via hole is connected to the guide groove.

3. The method for preparing the driving backplane according to claim 2, further comprising forming a second conductor part upon forming the raw material part by patterning the doped amorphous silicon layer, wherein the second conductor part is connected to the raw material part and is formed on a side of the raw material part away from the first conductor part.

4. The method for preparing the driving backplane according to claim 3, wherein the raw material part is formed within the guide groove, and the second conductor part is formed on a side of the guide groove away from the first conductor part.

5. The method for preparing the driving backplane according to claim 2, wherein the inducing particles are formed within the guide groove, and a diameter of the inducing particles is greater than or equal to 100 nanometers and less than or equal to 300 nanometers.

6. The method for preparing the driving backplane according to claim 2, wherein a width of the guide groove in a second direction is greater than or equal to 1 micron and less than or equal to 5 microns, and a depth of the guide groove in a third direction is greater than or equal to 100 nanometers and less than or equal to 120 nanometers, where the second direction is perpendicular to the first direction, and the third direction is perpendicular to both the first direction and the second direction.

7. The method for preparing the driving backplane according to claim 2, wherein the first channel part is formed by growing along a groove sidewall of the guide groove extending along the first direction.

8. The method for preparing the driving backplane according to claim 1, wherein said forming the inducing particles comprises:
forming an inducing layer on the side of the insulating layer group away from the base substrate; and
forming the inducing particles by performing pattern processing and reduction processing on the inducing layer, wherein a material of the inducing layer is indium tin oxide or indium, and the inducing particles are indium metal particles.

9. The method for preparing the driving backplane according to claim 1, wherein a material of the doped amorphous silicon layer is N-type doped amorphous silicon, and the first channel part is a polysilicon nanowire.

10. The method for preparing the driving backplane according to claim 9, wherein the first channel part further comprises residue of the inducing particles and N-type doping.

11. The method for preparing the driving backplane according to claim 1, wherein the connecting layer is a second active layer, the second active layer comprises a second channel part and a third conductor part provided at both ends of the second channel part, and the first conductor part is connected to the third conductor part.

12. A driving backplane, comprising:
a base substrate;
a connecting layer, provided on a side of the base substrate;
an insulating layer group, provided on a side of the connecting layer away from the base substrate, wherein the insulating layer group is provided with a first via hole, and the first via hole is connected to the connecting layer;
a first conductor part, provided within the first via hole, wherein the first conductor part is connected to the connecting layer;
a first channel part, provided on a side of the insulating layer group away from the base substrate and connected to the first conductor part, wherein an orthographic projection of the first channel part on the base substrate overlaps with an orthographic projection of the connecting layer on the base substrate.

13. The driving backplane according to claim 12, wherein a guide groove is provided on a surface of the insulating layer group away from the base substrate, the guide groove extends along a first direction, and the first channel part is located on a groove sidewall of the guide groove extending along the first direction.

14. The driving backplane according to claim 13, further comprising:
a second conductor part, provided on the side of the insulating layer group away from the base substrate, wherein the second conductor part is connected to the first channel part, and is located on a side of the guide groove away from the first conductor part.

15. The driving backplane according to claim 14, further comprising:
inducing particles, provided between the second conductor part and the first channel part, or between the first conductor part and the first channel part.

16. The driving backplane according to claim 15, wherein the first channel part is a polysilicon nanowire, and the first channel part further comprises residue of the inducing particles and N-type doping.

17. The driving backplane according to claim 15, wherein the connecting layer is a second active layer, the second active layer comprises a second channel part and a third conductor part provided at both ends of the second channel part, and the first conductor part is connected to the third conductor part.

18. The driving backplane according to claim 17, wherein the insulating layer group comprises a first gate insulating layer, a second gate insulating layer and a second buffer layer stacked in sequence, the first gate insulating layer is provided on a side of the connecting layer away from the base substrate, a second via hole is provided to penetrate through the first gate insulating layer and the second gate insulating layer, and the driving backplane further comprises:
a second gate, provided between the first gate insulating layer and the second gate insulating layer, and opposite to the first channel part;
a second source, provided between the second gate insulating layer and the second buffer layer, and connected to the third conductor part through the second via hole;
a third gate insulating layer provided on a side of the first channel part away from the base substrate;
a first gate, provided on a side of the third gate insulating layer away from the base substrate, and opposite to the first channel part;
a fourth gate insulating layer, provided on a side of the first gate away from the base substrate, wherein a third via hole is provided to penetrate through the third gate insulating layer and the fourth gate insulating layer; and
a first source, provided on a side of the fourth gate insulating layer away from the base substrate, and is connected to the second conductor part through the third via hole.

19. The driving backplane according to claim 17, further comprising:
a third thin film transistor, provided on a side of the base substrate, wherein a third active layer of the third thin film transistor is provided in a same layer and a same material as the second active layer;
a fourth thin film transistor, provided on the side of the base substrate, wherein a fourth active layer of the fourth thin film transistor is provided in the same layer and the same material as the second active layer;
a fifth thin film transistor, provided on a side of the third thin film transistor away from the base substrate; and
a sixth thin film transistor, provided on a side of the fourth thin film transistor away from the base substrate.

20. A display device, comprising a driving backplane, wherein the driving backplane comprises:
a base substrate;
a connecting layer, provided on a side of the base substrate;
an insulating layer group, provided on a side of the connecting layer away from the base substrate, wherein the insulating layer group is provided with a first via hole, and the first via hole is connected to the connecting layer;
a first conductor part, provided within the first via hole, wherein the first conductor part is connected to the connecting layer;
a first channel part, provided on a side of the insulating layer group away from the base substrate and connected to the first conductor part, wherein an orthographic projection of the first channel part on the base substrate overlaps with an orthographic projection of the connecting layer on the base substrate.
